(19) United States
(12) Patent Application Publication
(10) Pub. No.: US 2018/0093461 A1
(43) Pub. Date: Apr. 5, 2018

(54) RESIN COMPOSITION, POLYIMIDE RESIN FILM, AND METHOD FOR PRODUCING SAME

(71) Applicant: ASAHI KASEI KABUSHIKI KAISHA, Tokyo (JP)

(72) Inventors: Yuka UTASHIRO, Tokyo (JP); Yasuhito IIZUKA, Tokyo (JP)

(73) Assignee: ASAHI KASEI KABUSHIKI KAISHA, Tokyo (JP)

(21) Appl. No.: 15/564,861

(22) PCT Filed: Apr. 13, 2016
(86) PCT No.: PCT/JP2016/061941

§ 371 Date: Oct. 6, 2017

(30) Foreign Application Priority Data
Apr. 17, 2015 (JP) 2015-085433

(51) Int. Cl. B32B 27/28; C08K 5/5419; C08L 79/08; C08G 73/10; H05K 1/03

(52) U.S. Cl. CPC B32B 27/281; C08K 5/5419; C08L 79/08; C08L 2203/16; H05K 1/0313; C08L 2203/206; C08G 73/1007

(57) ABSTRACT

Provided is a resin composition characterized by containing (a) a polyimide precursor that has a 308 nm absorbance of 0.1-0.8 when formed into 0.1-μm-thick polyimide resin film by heating for one hour at 350° C., and (b) an alkoxysilane compound having a 308 nm absorbance of 0.1-1.0 at a solution thickness of 1 cm when made into a 0.001-mass % NMP solution.

### TECHNICAL FIELD

The present invention relates to a resin composition used in, for example, a substrate for a flexible device, a polyimide resin film, and a method for producing the same.

### BACKGROUND ART

Films made of polyimide (PI) resin are commonly used as resin films in applications requiring high levels of heat resistance. Typical polyimide resins are highly heat resistant resins produced by subjecting an aromatic tetracarboxylic dianhydride and an aromatic diamine to solution polymerization to produce a polyimide precursor, followed by ring closure and dehydration and subjecting to thermal imidization at a high temperature, or chemical imidization using a catalyst.

Polyimide resins are insoluble, infusible, ultra-heat resistant resins that have superior properties such as thermal oxidation resistance, heat resistance, radiation resistance, low-temperature resistance and chemical resistance. Consequently, polyimide resins are used in a wide range of fields, including electronic materials such as insulating coating agents, insulating films, semiconductors or the electrode protective films of TFT-LCD, and more recently, the use of polyimide resins is being considered for use as colorless, transparent flexible substrates by utilizing the light weight and flexibility thereof as an alternative to glass substrates conventionally used in the field of display materials in the manner of liquid crystal alignment films.

In the case of using a polyimide resin as a flexible substrate, a process is widely used that comprises coating a varnish containing polyimide resin or a precursor thereof along with other components on a suitable support such as a glass substrate, drying to form a film, and forming an element or circuit on the film followed by separating the film from the glass substrate,

Thus, in the case of applying a polyimide resin film to a flexible substrate, it is required to realize the offsetting properties of adhesiveness to and detachability from the substrate.

In response to this problem, a resin composition has been disclosed that contains a compound having a specific chemical structure (Patent Document 1),

### PRIOR ART DOCUMENTS

### Patent Documents

Patent Document 1: International Publication No. WO 2014/073591

### DISCLOSURE OF THE INVENTION

### Problems to be Solved by the Invention

However, this known resin composition does not have adequate properties for applying as, for example, a semiconductor insulating film, TFT-LCD insulating film, electrode protective film, ITO electrode substrate for a touch panel, or heat-resistant, colorless and transparent substrate for a flexible display.

Patent Document 1 explains that the resin composition described in this publication achieves a superior balance between adhesiveness and detachability. However, according to the technology of Patent Document 1, adhesiveness is inadequate and there is still room for improvement.

Processes for separating a film from a support using a so-called “laser lift off technique”, which uses a laser in the separation step, have come to be used in recent years. The aforementioned Patent Document 1 does not give any consideration whatsoever to the application of this laser lift off. When the inventors of the present invention confirmed the case of applying the technology of Patent Document 1 to the laser lift off technique, there was determined to also be room for improvement with respect to this point as well.

With the foregoing in view, an object of the present invention is to provide a resin composition containing a polyimide resin precursor, which in addition to having adequate transparency for use in a colorless, transparent flexible substrate, is capable of yielding a polyimide film that realizes both adequate adhesiveness with a support such as a glass substrate, and easy detachability in a separation step using laser lift off.

Another object of the present invention is to provide a polyimide resin film and a method for producing the same.

### Means for Solving the Problems

The inventors of the present invention conducted extensive studies to solve the aforementioned problems. As a result, it was found that, in a resin composition containing a polyimide precursor and an alkoxysilane, in the case each is used by combining types thereof that exhibit absorbance of a specific range in response to light of a specific wavelength, a polyimide resin film is imparted that realizes both adequate transparency and adequate adhesiveness to the support, while also being able to be easily detached in a separation step using laser lift off, thereby leading to the present invention on the basis of these findings.

Namely, the present invention is as indicated below.

[1] A resin composition including:

(a) a polyimide precursor having absorbance at 308 nm of 0.1 to 0.8 when heated for 1 hour at 350° C. to form, a polyimide resin film having a film thickness of 0.1 μm., and

(b) an alkoxysilane compound having absorbance at 308 nm of 0.1 to 1.0 when in the form of a 0.001% by weight NMP solution at a solution thickness of 1 cm.

[2] The resin composition described in [1], wherein the alkoxysilane compound of (b) is the reaction product of a tetracarboxylic dianhydride represented by the following general formula (1):

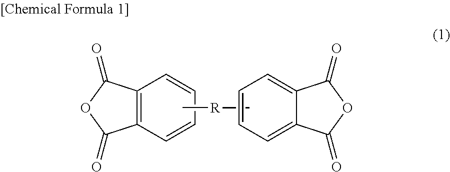

(wherein, R represents a single bond, oxygen atom, sulfur atom, carbonyl group or alkylene group having 1 to 5 carbon atoms), and

an aminotrialkoxysilane compound.

[3] The resin composition described in [1], wherein the alkoxysilane compound of (b) is at least one type of compound selected from the group of consisting of compounds respectively represented by the following general formulas (2) to (4), (9) and (10).

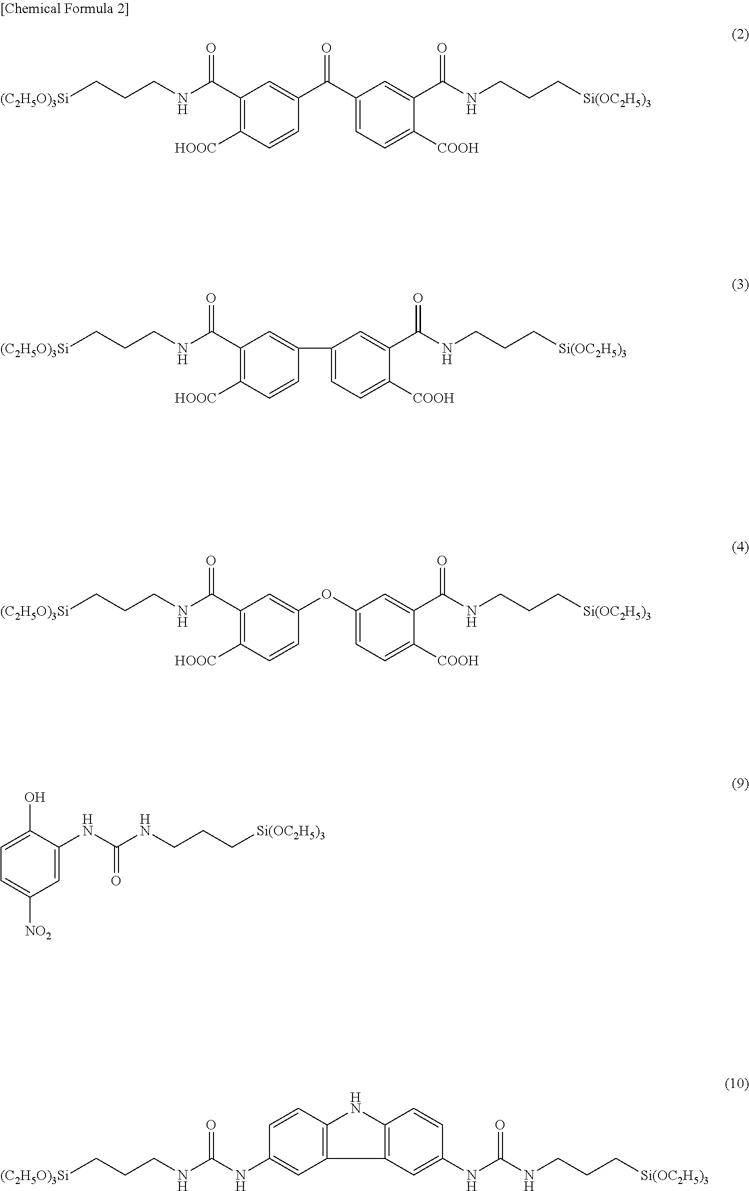

[4] The resin composition described in any of [1] to [3], wherein the polyimide precursor of (a) has one or more structural units selected from the structural units respectively represented by the following formulas (5) and (6):

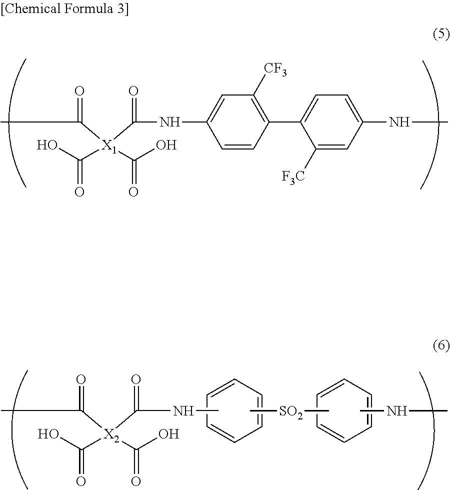

(wherein, X₁ and X₂ respectively and independently represent a tetravalent organic group having 4 to 32 carbon atoms).

[5] The resin composition described in [4], wherein the polyimide precursor of (a) has a structural unit represented by the following formula (5-1):

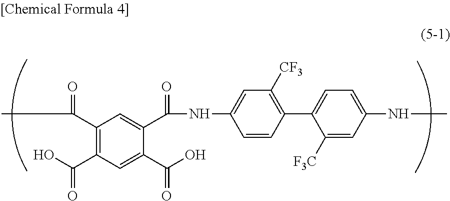

and a structural unit represented by the following formula (5-2).

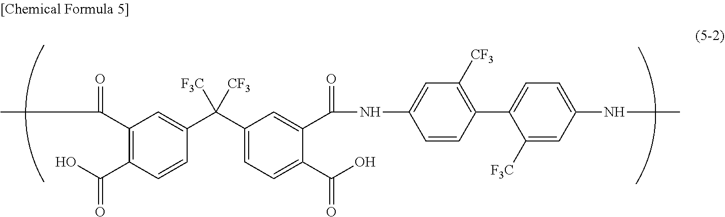

[6] The resin composition described in [5], wherein the molar ratio of the structural unit represented by the formula (5-1) to the structural unit represented by the formula (5-2) is 90/10 to 50/50.

[7] The resin composition described in [4], wherein the polyimide precursor of (a) has a structural unit represented by the following formula (6-1).

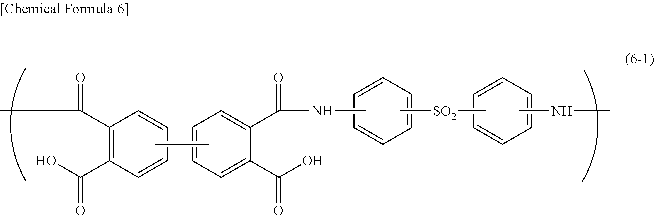

[8] A polyimide resin film, which is a cured product of the resin composition described in any of [1] to [7].

[9] A resin film, containing the polyimide resin film described in [8].

[10] A method for producing a polyimide resin film, including:

a step for coating the resin composition described in any of [1] to [7] on the surface of a support,

a step for drying the coated resin composition and removing the solvent,

a step for heating the support and the resin composition to form a polyimide resin film, and

a step for separating the polyimide resin film from the support.

[11] The method for producing a polyimide resin film described in [10], wherein the step for separating the polyimide resin film from the support includes a step for separating the polyimide resin film after irradiating with laser light from the support side.

[12] A laminate, containing a support and a polyimide resin film which is a cured product of the resin composition described in any of [1] to [7] on the surface of the support.

[13] A method for producing a laminate, including:

a step for coating the resin composition described in any of [1] to [7] on the surface of a support,

a step for drying the coated resin composition and removing the solvent, and

a step for heating the support and the resin composition to form a polyimide resin film.

[14] A method for producing a display substrate, including:

a step for coating the resin composition described in any of [1] to [7] on a support,

a step for drying the coated resin composition and removing the solvent,

a step for heating the support and the resin composition to form a polyimide resin film,

a step for forming an element or circuit on the polyimide resin film, and

a step for separating the polyimide resin film having an element or circuit formed thereon from the support,

### EFFECTS OF THE INVENTION

The resin composition containing a polyimide precursor according to the present invention yields a polyimide resin, which in addition to having adequate transparency for application as a colorless, transparent flexible substrate, is capable of yielding a polyimide film that realizes both adequate adhesiveness with a support such as a glass substrate, and easy detachability in a separation step using laser lift off.

### BEST MODE FOR CARRYING OUT THE INVENTION

The following provides a detailed explanation of embodiments exemplifying the present invention (to be abbreviated as the “embodiments”). The present invention is not limited to the following embodiments and can be modified in various ways within the scope of the gist thereof. It should be noted that structural units in the formulas of the present disclosure are not intended to represent specific bonding modes such as a block structure. The characteristic values described in the present disclosure are intended to indicate values measured using the methods described in the section entitled “Examples” or methods which are understood to be equivalent thereto by persons with ordinary skill in the art.

<Resin Composition>

The resin composition provided by one embodiment of the present invention (to be referred to as the “present embodiment”) contains a polyimide precursor (a) and an alkoxysilane compound (b).

The following provides a sequential explanation of each component contained in the resin composition of the present embodiment.

[Polyimide Precursor (a)]

The polyimide precursor (a) in the present embodiment is a polyimide precursor having absorbance at 308 nm of 0.1 to 0.8 when heated for 1 hour at 350° C. to form polyimide resin film having a film thickness of 0.1 μm. By making this absorbance to be 0.8 or less, absorbance in the visible light region is adequately inhibited, thereby enabling application to a flexible transparent substrate and inhibition of discoloration of the polyimide resin film following laser lift off.

Although the mechanism of laser lift off is still not clear, the polyimide resin film is presumed to separate from the support as a result of partially gasifying a portion derived from at least one of the polyimide precursor (a) and alkoxysilane compound (b) present in the polyimide resin film in the vicinity of the support with laser light irradiated at a wavelength of 308 nm. However, in the case the absorbance of the resin film exceeds 0.8, a large amount of gas is generated in a short period of time, and as a result thereof, the resin film is presumed to become discolored following separation. The aforementioned absorbance is preferably 0.7 or less and particularly preferably 0.6 or less from the viewpoint of more effectively inhibiting discoloration of the resin film following separation.

By making the aforementioned absorbance to be 0.1 or more, the resin film can be easily separated even by low-energy irradiation. In the case the aforementioned absorbance is less than 0.1, the resin film on the substrate is unable to absorb an amount of energy required for gasification, thereby preventing separation even in the case of using the alkoxysilane compound (b) to be subsequently described. From this viewpoint, the aforementioned absorbance is more preferably 0.2 or more and particularly preferably 0.3 or more.

The polyimide precursor (a) in the present embodiment is a polyamic acid obtained by reacting a tetracarboxylic dianhydride and a diamine.

Specific examples of the aforementioned tetracarboxylic dianhydride include 4,4′-(hexafluoroisopropylidene)diphthalic anhydride (6FDA), 5-(2,5-dioxotetrahydro-3-furanyl)-3-methyl-dichlorhexene-1,2-dicarboxylic anhydride, pyromellitic dianhydride (PMDA), 1,2,3,4-benzenetetracarboxylic dianhydride, 3,3′,4,4′-benzophenonetetracarboxylic dianhydride, 2,2′3,3′-benzophenonetetracarboxylic dianhydride, biphenyltetracarboxylic dianhydride (BPDA), methylene-4,4′-diphthalic dianhydride, 1,1-ethylidene-4, 4′-diphthalic dianhydride, 2,2-propylidene-4,4′-diphthalic dianhydride, 1,2-ethylene-4,4′-diphthalic dianhydride, 1,3-trimethylene-4,4′-diphthalic dianhydride, 1,4-tetramethylene-4,4′-diphthalic dianhydride, 1,5-pentamethylene-4,4′-diphthalic dianhydride, 4,4′-biphenylbis(trimellitic monoester anhydride) (TAHQ), 4,4′-oxydiphthalic dianhydride (ODPA), thio-4,4′-diphthalic dianhydride, sulfonyl-4,4′-diphthalic dianhydride, 1,3-bis(3,4-dicarboxyphenyl)benzene dianhydride, 1,3-bis(3,4-dica rboxyphenoxy)benzene dianhydride, 1,4-bis(3,4-dicarboxyphenoxy)benzene dianhydride, 1,3-bis [2-(3,4-dicarboxyphenyl)-2-propyl]benzene dianhydride, 1,4-bis[2-(3,4-dicarboxyphenyl)-2-propyl]benzene dianhydride, bis [3-(3,4-dicarboxyphenoxy)phenyl]methane dianhydride, bis [4-(3,4-dicarboxyphenoxy)phenyl]methane dianhydride, 2,2-bis [3-(3,4-dicarboxyphenoxy)phenyl]propane dianhydride, 2,2-bis [4 -(3,4-dicarboxyphenoxy)phenyl]propane dianhydride, bis(3,4-dicarboxyphenoxy)dimethylsilane dianhydride, 1,3-bis(3,4 -dicarboxyphenyl)-1,1,3,3-tetramethyldisiloxane dianhydride, 2,3,6,7-naphthalenetetracarboxylic dianhydride, 1,4,5,8-naphthalenetetracarboxylic dianhydride,1,2,5,6-naphthalenetetracarboxylic dianhydride, 3,4,9,10-perylenetetracarboxylic dianhydride, 2,3,6,7-anthracenetetracarboxylic dianhydride, 1,2,7,8-phenanthrenetetracarboxylic dianhydride, ethylenetetracarboxylic dianhydride, 1,2,3,4-butanetetracarboxylic dianhydride, 1,2,3,4-cyclobutanetetra carboxylic dianhydride, cyclopentanetetracarboxylic dianhydride, cyclohexane-1,2,3,4-tetracarboxylic dianhydride, cyclohexane-1,2,4,5-tetracarboxylic dianhydride (CHDA) , 3,3′4,4′-bicyclohexyltetracarboxylic dianhydride, carbonyl-4,4′-bis(cyclohexane-1,2-dicarboxylic) dianhydride, methylene-4,4′-bis (cyclohexane-1,2-dicarboxyic) dianhydride, 1,2-ethylene-4,4′-bis(cyclohexane-1,2-dicarboxylic) dianhydride, 1,1-ethylidene-4,4′-bis(cyclohexane-1,2-dicarboxylic) dianhydride, 2,2-propylidene-4,4′-bis(cyclohexane-1,2-dicarboxylic) dianhydride, oxy-4,4′-bis(cyclohexane-1,2-dicarboxylic) dianhydride, thio-4,4′-bis(cyclohexane-1,2-dicarboxylic) dianhydride, sulfonyl-4,4′-bis(cyclohexane-1,2-dicarboxylic) dianhydride, bicyclo[2,2,2]oct-7-ene-2,3,5,6-tetracarboxylic dianhydride, rel-[1S,5R,6R]-3-oxabicyclo[3,2,1]octan-2,4-dione-6-spiro-3′-(tetrahydrofuran-2′,5′-dione) , 4-(2,5-dioxotetrahydrofuran-3-yl)-1,2,3,4-tetrahydronaphthalene-1,2-dicarboxylic dianhydride and ethylene glycol-bis-(3,4-dicarboxylic anhydride phenyl) ether. 3,3′,4,4′-biphenyltetracarboxylic dianhydride is preferable for the aforementioned biphenyltetracarboxylic dianhydride.

Specific examples of the aforementioned diamines include 4,4′-(diaminodiphenyl)sulfone (4,4′-DAS), 3,4′-(diaminodiphenyl)sulfone, 3,3′-(diaminodiphenyl)sulfone, 2,2′-bis(trifluoromethyl)benzidine (TFMB), 2,2-dimethyl-4,4′-diaminobiphenyl, 1,4-diaminobenzene (p-PD), 1,3-diaminobenzene, 4-aminophenyl-4′-aminobenzoate, 4,4′-diaminobenzoate, 4,4′- (or 3,4′-, 3,3′- or 2,4′-) diaminodiphenyl ether, 4,4′-(or 3,3′-) diaminodiphenylsulfone, 4,4′- (or 3,3′-) diaminodiphenylsulfide 4,4′-benzophenonediamine, 3,3′-benzophenonediamine, 4,4′-di(4-aminophenoxy)phenylsulfone, 4,4′-di (3-aminophenoxy)phenylsulfone, 4,4′-bis(aminophenoxy)biphenyl, 4,4′-bis(aminophenoxy)benzene, 1,3-bis(4-aminophenoxy)benzene, 2-bis{4-(4-aminophenoxy)phenyl}propane, 3,3′,5,5′-tetramethyl-4,4′-diaminodiphenylmethane, 2,2-bis(4-aminophenyl)propane, 2,2′6,6′-tetramethyl-4,4′-diaminobiphenyl, 2,2′6,6′-tetratrifluoromethyl-4,4′-diaminobiphenyl, bi s{ (4-aminophenyl)-2-propyl}1,4-benzene, 9,9-bis(4-aminophenyl)fluorene, 9,9-bis (4-aminophenoxyphenyl)fluorene, 3,3′-dimethylbenzidene, 3,3′-dimethoxybenzidine, 3,5-diaminobenzoic acid, 2,6-diaminopyridine, 2,4-diaminopyridine, bis(4-aminophenyl-2-propyl)-1,4-benzene, 3,3′-bis(trifluoromethyl)-4,4′-diaminobiphenyl (3,3′-TFDB), 2,2′-bis[3-(3-aminophenoxy)phenyl]hexafluoropropane (3-BDAF), 2,2′bis[4-(4-aminophenoxy)phenyl]hexafluoropropane (4-BDAF), 2,2′-bis(3-aminophenyl)hexafluoropropane (3,3′-6F) and 2,2′-bis(4-aminophenyl)hexafluoropropane (4,4′-6F).

There are no limitations on the structure of the polyimide precursor (a) in the present embodiment provided it satisfies the aforementioned requirements. However, from the viewpoint of inhibiting YI, the polyimide precursor (a) preferably has one or more types of structural units selected from the structural units represented by the following formulas (5) and (6):

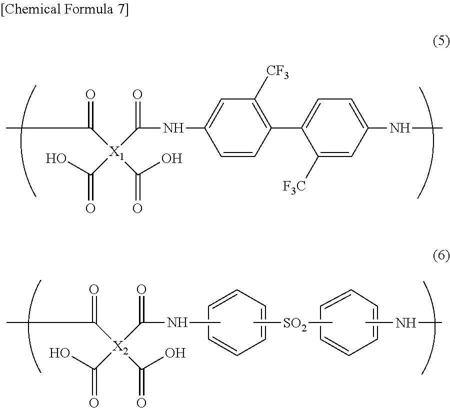

(wherein, X₁ and X₂ respectively and independently represent a tetravalent organic group having 4 to 32 carbon atoms).

From the viewpoint of inhibiting the coefficient of linear expansion (CTE) when the resin composition of the present invention is in the form of a cured film to as low a value as possible, the polyimide precursor (a) preferably has a structural unit represented by the aforementioned formula (5), and from the viewpoint of lowering YI and birefringence when the resin composition of the present invention is in the form of a cured film, the polyimide precursor (a) preferably has a structural unit represented by the aforementioned formula (6).

X₁ in the aforementioned formula (5) and X₂ in the aforementioned formula (6) respectively represent a structural unit derived from a tetracarboxylic dianhydride, and is a tetravalent group obtained by removing two acid anhydride groups from the tetracarboxylic dianhydride used.

X₁ in the aforementioned formula (5) is preferably a tetravalent group derived from one or more types of tetracarboxylic dianhydrides selected from the group consisting of PMDA, BPDA, ODPA, 6FDA and TAHQ. X₁ in the aforementioned formula (5) preferably contains both a tetravalent group derived from PMDA and a tetravalent group derived from BPDA from the viewpoints of reducing residual stress, increasing Tg and improving mechanical elongation, and preferably contains both a tetravalent group derived from PMDA and a tetravalent group derived from ODPA or 6FDA from the viewpoints of lowering YI and improving mechanical elongation. X₁ in the aforementioned formula (5) preferably contains both a tetravalent group derived from PMDA and a tetravalent group derived from TAHQ from the viewpoints of lowering YI, increasing Tg and improving mechanical elongation.

The polyimide precursor (a) having a structural unit represented by the aforementioned formula (5) is preferably a polyimide precursor having a structural unit represented by the following formula (5-1):

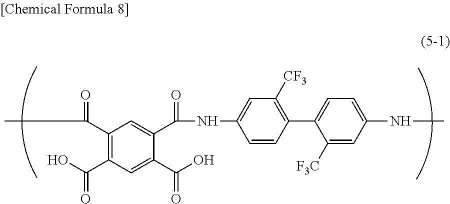

and a structural unit represented by the following formula (5-2).

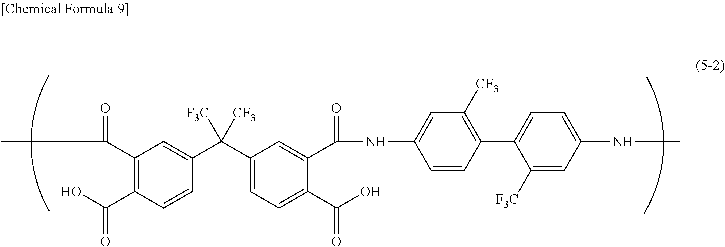

The molar ratio of the structural units (5-1) and (5-2) of the aforementioned copolymer is preferably such that the ratio of (5):(6) is 90:10 to 50:50 from the viewpoints of CTE and yellowness index (YI) of the resulting polyimide resin film. The aforementioned ratio of (5) to (6) can be determined from, for example, the results of ¹H-NMR spectral analysis. The copolymer may be a block copolymer or random copolymer.

This polyimide precursor (copolymer) can be obtained by copolymerizing PMDA and 6FDA with TFMB. Namely, structural unit (5-1) is formed by polymerizing PMDA and TFMB, while structural unit (5-2) is formed by polymerizing 6FDA and TFMB. The ratio between the aforementioned structural units (5-1) and (5-2) can be adjusted by changing the usage ratios of PMDA and 6FDA.

The polyimide precursor (a) in the present embodiment may also contain a structural unit other than the structural unit represented by the aforementioned formula (5) within a range that does not impair the intended performance of the present invention.

The amount of the aforementioned structural unit (5) of the polyimide precursor (copolymer) (a) in the present embodiment is preferably 30% by weight or more from the viewpoint of low CTE, and preferably 70% or more from the viewpoint of low YI, based on the total weight of the copolymer. The amount of the aforementioned structural unit (5) is most preferably 100% by weight.

X₂ in the aforementioned formula (6) is preferably a tetravalent group derived from one or more types of tetracarboxylic dianhydrides selected from the group consisting of PMDA, BPDA, ODPA, 6FDA and TAHQ. X₂ in formula (6) preferably contains a tetravalent group derived from PMDA or BPDA from the viewpoints of reduction of residual stress, increase of Tg and improvement of mechanical elongation, preferably contains a tetravalent group derived from ODPA or 6FDA from the viewpoints of lowering of YI and improvement of mechanical elongation, and preferably includes a tetravalent group derived from TAHQ from the viewpoints of lowering of YI, increase of Tg and improvement of mechanical elongation,

X₂ in the aforementioned formula (6) preferably contains a tetravalent group derived from BPDA. The polyimide precursor in this case has a structural unit represented by the following formula (6-1).

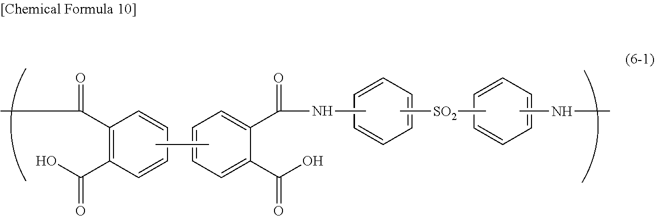

The biphenyl unit on the left side of the aforementioned formula (6-1) is preferably bonded at the 3,3′ position or 3,4′ position. This polyimide precursor can be obtained by polymerizing BPDA and 4,4′-DAS. At this time, another tetracarboxylic dianhydride may be used together with BPDA and another diamine may be used together with 4,4′-DAS.

The polyimide precursor (a) in the present embodiment may also contain a structural unit other than the structural unit represented by the aforementioned formula (5) within a range that does impair the intended performance of the present invention.

The amount of the aforementioned structural unit (6) in the polyimide precursor (copolymer) (a) according to the present embodiment is preferably 30% by weight or more from the viewpoint of low birefringence and preferably 70% by weight or more from the viewpoint of low YI, based on the total weight of the copolymer. The amount of the aforementioned structural unit (6) is most preferably 100% by weight.

The polyimide precursor (a) in the present embodiment is most preferably a polyimide precursor having only the structural unit represented by the aforementioned formula (5) or a polyimide precursor having only the structural unit represented by the aforementioned formula (6).

The molecular weight of the polyimide precursor (polyamic acid) (a) of the present invention in terms of the weight average molecular weight thereof is preferably 10,000 to 500,000, more preferably 10,000 to 300,000, and particularly preferably 20,000 to 200,000. If the weight average molecular weight is 10,000 or more, cracks do not form in the resin film and favorable mechanical properties can be obtained in the step for heating the coated resin composition. If the weight average molecular weight is 500,000 or less, the weight average molecular weight can be controlled during synthesis of the polyamic acid, or a resin composition can be obtained that has suitable viscosity.

The number average molecular weight of the polyimide precursor (a) according to the present embodiment is preferably 3,000 to 500,000, more preferably 5,000 to 500,000, even more preferably 7,000 to 300,000 and particularly preferably 10,000 to 250,000. The number average molecular weight is preferably 3,000 or more from the viewpoints of obtaining favorable heat resistance and strength (such as elongation strength), and preferably 500,000 or less from the viewpoints of solubility of the polyimide precursor (a) in solvent and enabling coating at a desired thickness during coating without the occurrence of bleeding. The number average molecular weight is preferably 50,000 or more from the viewpoint of obtaining high mechanical elongation.

In the present disclosure, weight average molecular-weight and number average molecular weight are values that are respectively measured in terms of standard polystyrene using gel permeation chromatography.

In a preferable aspect thereof, a portion of the structure of the polyimide precursor (a) may also be imidated, the details of which will be subsequently described.

The polyimide precursor (polyamic acid) (a) in the present embodiment can be synthesized by a conventionally known synthesis method. For example, a prescribed type and amount of diamine is dissolved in a solvent to obtain a solution followed by adding a prescribed type and amount of tetracarboxylic dianhydride to the solution and stirring.

Heating may be carried out as necessary when dissolving each monomer. The reaction temperature is preferably −30° C. to 200° C., more preferably 20° C. to 180° C., and particularly preferably 30° C. to 100° C. The reaction is preferably carried out for 3 hours to 100 hours, and polymerization is completed within this time frame. More specifically, after holding the temperature at the aforementioned preferable reaction temperature for the aforementioned preferable reaction time, stirring is continued while still at room temperature (20° C. to 25° C.) or at a suitable reaction temperature, and the endpoint of the reaction is taken to be the point at which a desired molecular weight has been reached as determined by GPC.

All or a portion of the carboxylic acid of the polyamic acid may be esterified by adding N,N-dimethylformamide dimethyl acetal or N,N-dimethylformamide diethyl acetal to the polyamic acid obtained in the manner described above followed by heating. As a result of this treatment, stability of the viscosity of the solution containing the polyimide precursor (a) and solvent can be improved during room temperature storage.

An ester-modified polyamic acid like that described above can also be synthesized by pre-esterification in addition to the aforementioned post-esterification. Namely, an ester-modified polyamic acid can also be obtained by preliminarily reacting a monovalent alcohol with the aforementioned tetracarboxylic dianhydride in an amount equal to one equivalent based on the acid anhydride groups thereof, followed by reacting with a dehydration condensation agent such as thionyl chloride or dicyclohexylcarbodiimide and then subjecting to a condensation reaction with a diamine.

There are no particular limitations on the solvent of the aforementioned polymerization reaction provided it is capable of dissolving the diamine, tetracarboxylic dianhydride and the resulting polyamic acid. Specific examples of such solvents include aprotic solvents, phenol-based solvents, ether-based solvents and glycol-based solvents.

More specifically, examples of aprotic solvents include amide-based solvents such as N,N-dimethylformamide (DMF), N,N-dimethylacetoamide (DMAc), N-methyl-2-pyrrolidone (NMP), N-methylcaprolactam, 1,3-dimethylimidazolidinone, tetramethyl urea or compounds represented by the following general formula (8):

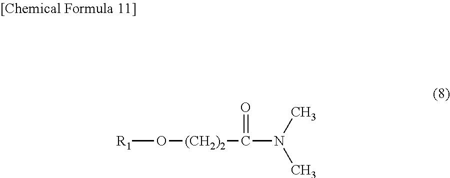

(wherein, R₁ represents a methyl group or n-butyl group); lactone-based solvents such as γ-butyrolactone or γ-valerolactone; phosphorous-containing amide-based solvents such as hexamethylphosphoric amide or hexamethylphosphine triamide; sulfur-based solvents such as dimethyl sulfone, dimethyl sulfoxide or sulfolane; ketone-based solvents such as cyclohexanone or methylcyclohexanone; tertiary amine-based solvents such as picoline or pyridine; and ester-based solvent such as 2-methoxy-1-methylethyl acetate. Compounds represented by the aforementioned formula (8) can be acquired as commercially available products. Examples thereof include Ekuamido M100 (R₁ represents a methyl group) and Ekuamido B100 (R₁ represents an n-butyl group) manufactured by Idemitsu Kosan Co., Ltd.

Examples of phenol-based solvents include phenol, o-cresol, m-cresol, p-cresol, 2,3-xylenol, 2,4-xylenol, 2,5-xylenol, 2,6-xylenol, 3,4-xylenol and 3,5-xylenol.

Examples of ether-based and glycol-based solvents include 1,2-dimethoxyethane, bis(2-methoxyethyl) ether, 1,2-bis(2-methoxyethoxy) ethane, bis [2-(2-methoxyethoxy)ethyl] ether, tetrahydrofuran and 1,4-dioxane,

Among these solvents, a solvent having a boiling point at normal pressure within the range of 60° C. to 300° C. is preferable, that having a boiling point at normal pressure within the range of 140° C. to 280° C. is more preferable, and that having a boiling point at normal pressure within the range of 170° C. to 270° C. is particularly preferable. If the boiling point of the solvent is 300° C. or lower, the duration of the drying step during film formation can be shortened. As a result of making the boiling point of the solvent to be 60° C. or higher, a uniform resin film free of surface roughness and air bubbles can be obtained in the drying step.

The vapor pressure of the organic solvent at 20° C. is preferably 250 Pa or lower for similar reasons.

The boiling point of the organic solvent is therefore preferably 170° C. to 270° C. and the vapor pressure at 20° C. is preferably 250 Pa or lower from the viewpoints of solubility and edge cissing during coating. More specifically, preferable examples of solvent include N-methyl-2-pyrrolidone, γ-butyrolactone, Ekuamido M100 and Ekuamido B100. One type of these solvents may be used alone or two or more types may be used as a mixture.

The polyimide precursor (polyamic acid) (a) in the present invention is obtained in the form of a solution (to also be referred to as the “polyamic acid solution”) containing as solvent an organic solvent as exemplified above. The ratio of the polyamic acid component based on the total weight of the resulting polyamic acid solution is preferably 5% by weight to 60% by weight, more preferably 10% by weight to 50% by weight, and particularly preferably 10% by weight to 40% by weight from the viewpoint of coating film formability.

The viscosity of a solution of the aforementioned polyamic acid solution at 25° C. is preferably 500 mPa·s to 200,000 mPa·s, more preferably 2,000 mPa·s to 100,000 mPa·s, and particularly preferably 3,000 mPa·s to 30,000 mPa·s. The viscosity of this solution can be measured using an E-type viscometer (such as Visconice HD manufactured by Toki Sangyo Co., Ltd.). A solution viscosity of 300 mPa·s or more facilitates coating during film formation. A solution viscosity of 200,000 mPa·s or less facilitates stirring during synthesis of the polyimide precursor (a).

Even if the viscosity of the solution has become high during synthesis of the polyamic acid, a polyamic acid solution having a viscosity that facilitates handling can be obtained by adding solvent and stirring following completion of the reaction.

Since the polyimide precursor (a) of the present embodiment allows the obtaining of a polyimide film such that YI is 15 or less at a film thickness of 10 μm, it has the advantage of being easily applied to the production process of a display equipped with a TFT element device on a colorless, transparent polyimide substrate. In a preferable aspect of the present embodiment, yellowness index YI of a resin film having a thickness of 10 μm, obtained by dissolving the polyimide precursor (a) in a solvent (such as N-methyl-2-pyrrolidone) and coating the resulting solution onto the surface of a support followed by heating the solution at 300° C. to 550° C. (such as 380° C.) in a nitrogen atmosphere (for 1 hour, for example), is 15 or less. In the case the film thickness is not 10 μm, the value for a thickness of 10 μm can be determined by a film thickness conversion technique using a method known among persons with ordinary skill in the art.

[Alkoxysilane Compound]

Next, an explanation is provided of the alkoxysilane compound (b) according to the present embodiment.

Absorbance at 308 nm of the alkoxysilane compound according to the present embodiment is 0.1 to 1.0 when in the form of a 0.001% by weight NMP solution at a solution thickness of 1 cm. There are no particular limitations on the structure thereof provided this requirement is satisfied. As a result of absorbance being within this range, the resulting resin film can be easily separated by laser lift off while retaining high transparency.

The aforementioned absorbance is preferably 0.12 or more and particularly preferably 0.15 or more from the viewpoint of facilitating laser lift off. The absorbance is preferably 0.4 or less and particularly preferably 0.3 or less from the viewpoint of transparency.

Optical absorbance at a wavelength of 308 nm of the alkoxysilane compound (b) according to the present invention is attributable to a functional group such as a benzophenone group, biphenyl group, diphenyl ether group, nitrophenol group or carbazole group present in the compound. The optical absorbance at a wavelength of 308 nm attributable to an alkoxysilane compound contained in conventionally known resin film precursor compositions was less than 0.1. The present invention uses a functional group having absorbance at a wavelength of 308 nm. As a result, film separation by low energy laser irradiation was made possible while inhibiting absorption in the visible light region by the resulting polyimide resin film.

The aforementioned alkoxysilane compound can be synthesized by, for example, a reaction between a tetracarboxylic dianhydride and an aminotrialkoxysilane compound, a reaction between a dicarboxylic anhydride and an aminotrialkoxysilane compound, a reaction between an amino compound and an isocyanatotrialkoxvsilane compound, or a reaction between an amino compound and a trialkoxysilane compound having an acid anhydride group. The aforementioned tetracarboxylic dianhydride, dicarboxylic anhydride and amino compound preferably each have an aromatic ring (and particularly, a benzene ring),

The alkoxysilane compound according to the present embodiment is preferably a reaction product of a tetracarboxylic dianhydride represented by the following general formula (1):

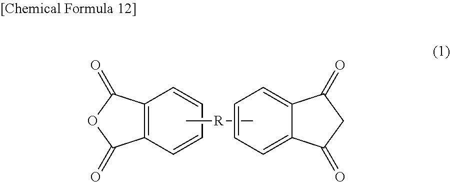

(wherein, R represents a carbonyl group, single bond, oxygen atom, sulfur atom or alkylene group having 1 to 5 carbon atoms) and an aminotrialkoxysilane compound, such as a compound respectively represented by the following formulas (9) and (10).

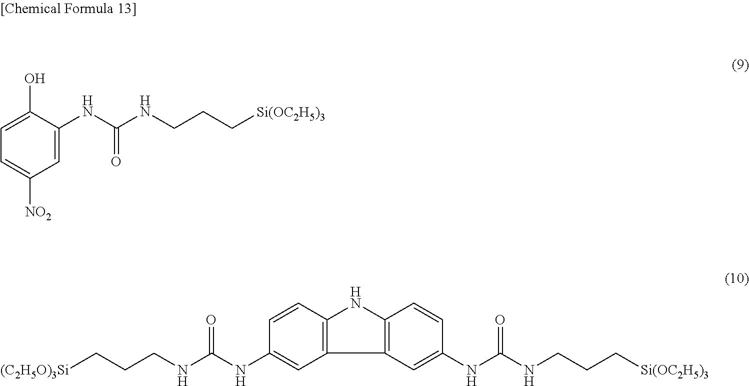

The reaction between the aforementioned tetracarboxylic dianhydride and aminotrialkoxysilane compound in the present embodiment can be carried out by, for example, dissolving 2 moles of aminotrialkoxysilane in a suitable solvent, adding 1 mole of tetracarboxylic dianhydride to the resulting solution, and reacting for preferably 0.5 hours to 8 hours at a reaction temperature of preferably 0° C. to 50° C.

Although there are no particular limitations thereon provided it dissolves the raw material compounds and product, the aforementioned solvent is preferably, for example, N-methyl-2-pyrrolidone, γ-butyrolactone, Ekuamido M100 (trade name, Idemitsu Kosan Co., Ltd.) or Ekuamido B100 (trade name, Idemitsu Kosan Co., Ltd.) from the viewpoint of compatibility with the aforementioned polyimide precursor (a).

The alkoxysilane compound according to the present embodiment is preferably at least one type of compound selected from the group consisting of compounds respectively represented by the aforementioned formulas (9) and (10) as well as the following general formulas (2) to (4) from the viewpoints of transparency, adhesiveness and detachability.

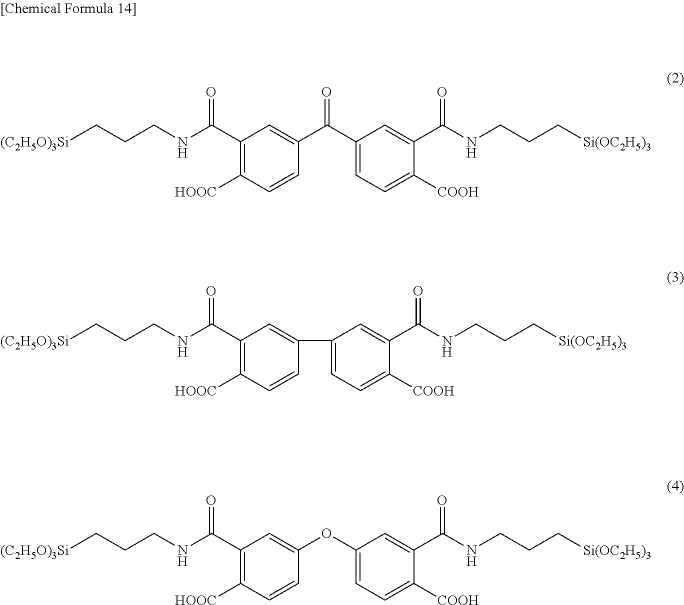

The content of the alkoxysiiane compound (b) in the resin composition according to the present embodiment can be suitably designed to be within a range over which adequate adhesiveness and detachability are demonstrated. An example of a preferable range thereof is 0.01% by weight to 20% by weight of the alkoxysiiane compound (b) to 100% by weight of the polyimide precursor (a).

As a result of making the content of the alkoxysiiane compound to be 0.01% by weight or more based on 100% by weight of the polyimide precursor (a), favorable adhesiveness with the support can be obtained in the resulting resin film. The content of the alkoxysiiane compound (b) is preferably 20% by weight or less from the viewpoint of storage stability of the resin composition. The content of the alkoxysiiane compound (b) is more preferably 0.02% by weight to 15% by weight, even more preferably 0.05% by weight to 10% by weight, and particularly preferably 0.1% by weight to 8% by weight based on the weight of the polyimide precursor (a).

<Resin Composition>

Another aspect of the present invention provides a resin composition containing the previously described polyimide precursor (a) and alkoxysilane compound (b), and further preferably contains an organic solvent (c). The resin composition is typically a varnish.

[Organic Solvent (c)]

There are no particular limitations on the organic solvent (c) in the present invention provided it dissolves the polyimide precursor (polyamic acid) (a) and the alkoxysilane compound (b). A solvent previously described as a solvent able to be used when synthesizing the aforementioned polyimide precursor (a) can be used for the organic solvent (c). The organic solvent (c) may be the same as or different from the solvent used when synthesizing the polyamic acid (a).

The amount of the organic solvent (c) used is preferably an amount such that the solid component concentration in the resin composition is 3% by weight to 50% by weight. The viscosity (25° C) of the resin composition is preferably 500 mPa-s to 100,000 mPa-s.

[Other Components]

The resin composition of the present invention may also contain a surfactant or leveling agent in addition to the aforementioned components (a) to (c).

(Surfactant or Leveling Agent)

The addition of a surfactant or leveling agent to the resin composition makes it possible to improve the coatability of the resin composition. More specifically, the addition of a surfactant or leveling agent makes it possible to prevent the occurrence of streaking in the coating film after coating.

Examples of such surfactants or leveling agents include silicone-based surfactants, fluorine-based surfactants and other nonionic surfactants. Specific examples thereof are respectively indicated below.

Silicone-based surfactants: Organosiloxane polymers KF-640, KF-642, KF-643, KP341, X-70-092, X-70-093, KBM303, KBM403, KBM803 (all trade names of products manufactured by Shin-Etsu Chemical Co., Ltd.); SH-28PA, SH-190, SH-193, SZ-6032, SF-8428, DC-57, DC-190 (all trade names of products manufactured by Dow Corning Toray Silicone Co., Ltd.); SILWET, L-77, L-7001, FZ-2105, FZ-2120, FZ-2154, FZ-2164, FZ-2166, L-7604 (all trade names of products manufactured by Unitika Ltd.); DBE-814, DBE-224, DBE-621, CMS-626, CMS-222, KF-352A, KF-354L, KF-355A, KF-6020, DBE-821, DBE-712 (all trade names of products manufactured by Gelest Inc.); BYK-307, BYK-310, BYK-378, BYK-333 (all trade names of products manufactured by Byk-Chemie Japan, K.K.); and Guranoru (trade name of product manufactured by Kyoei Chemical Co., Ltd.);

fluorine-based surfactants: Megaface Fill, F173, R-08 (all trade names of products manufactured by DIC Corp.); and Fluorad FC4430 and FC4432 (trade names of products manufactured by Sumitomo 3M, Ltd.); and,

other nonionic surfactants: polyoxyethylene lauryl ether, polyoxyethylene stearyl ether, polyoxyethylene oleyl ether and polyoxyethylene octyl phenol ether.

Among these surfactants, silicone-based surfactants or fluorine-based surfactants are preferable from the viewpoint of coatability of the resin composition (inhibition of streaking in the coating film), and silicone-based surfactants are more preferable from the viewpoints of decreasing the dependency of YI value and total light transmittance on oxygen concentration during curing.

In the case of using a surfactant or leveling agent, the incorporated amount thereof is preferably 0.001 part by weight to 5 parts by weight, and more preferably 0.01 part by weight to 3 parts by weight, based on 100 parts by weight of the polyimide precursor (a) in the resin composition.

After having prepared a resin composition containing each of the aforementioned components, a portion of the polyimide precursor (a) may be subjected to imidization to a degree that does not cause the precursor to precipitate by heating the resulting solution for 5minutes to 2 hours at 130° C. to 200° C. The imidization ratio can be controlled by suitably controlling the heating temperature and heating time. Partial imidization of the polyimide precursor (a) makes it possible to improve stability of the viscosity of the resin composition when storing at room temperature. A range of the imidization ratio of 5% to 70% is preferable from the viewpoint of maintaining balance between solubility of the polyimide precursor (a) and storage stability of the resin composition.

There are no particular limitations on the method for producing a resin composition of the present invention. For example, in the case the solvent used when synthesizing the polyimide precursor (a) and the organic solvent (c) are the same, the resin composition can be produced by adding the alkoxysiiane compound (b) and other components to a solution of the polyimide precursor (a). The solution may be stirred and mixed at room temperature as necessary following addition of the organic solvent (c) and other components. This stirring and mixing can be carried out using a suitable device such as a three-one motor equipped with a stirring blade (Shinto Scientific Co., Ltd.) or planetary centrifugal mixer. In the case of varnish having high viscosity, heat may be applied at 26° C. to 100° C. for the purpose of lowering viscosity.

In the case the solvent used when synthesizing the polyimide precursor (a) and the organic solvent (c) are different, the resin composition can be produced by removing the solvent present in the solution of the synthesized polyimide precursor by a suitable method such as re-precipitation or solvent distillation to obtain the polyimide precursor (a), followed by adding the organic solvent (c) and other components as necessary and stirring and mixing within a temperature range of room temperature to 80° C.

The moisture content of the resin composition according to the present embodiment is preferably 3,000 ppm or less, more preferably 1,000 ppm or less, and even more preferably 500 ppm or less from the viewpoint of stability of viscosity when storing the resin composition. The reason for the preferable storage stability in the case the moisture content of the resin composition is within the aforementioned ranges is unclear. However, this is thought to be due to moisture being involved in decomposition recombination of the polyimide precursor.

In a preferred aspect of the present invention, the yellowness index of a resin film having a thickness of 10 μm obtained by coating the resin composition of the present embodiment onto the surface of a support followed bv heating the resulting coating film at 300° C. to 550° C. in a nitrogen atmosphere is 15 or less. In the case the film thickness is not 10 μm, the value for a thickness of 10 μm can be determined by a film thickness conversion technique using a method known among persons with ordinary skill in the art.

The resin composition according to the present embodiment has superior room temperature storage stability, and the rate of change in viscosity in the case of having stored at room temperature for 2 weeks is 10% or less based on the initial viscosity. The resin composition according to the present embodiment does not require frozen storage and can be handled easily due to the superior room temperature storage stability thereof.

The resin composition of the present invention can be used to form a transparent substrate of a display device such as a liquid crystal display, organic electroluminescence display, field emission display or electronic paper. More specifically, the resin composition of the present embodiment can be used to form a substrate such as the substrate of a thin film transistor (TFT), substrate of a color filter or substrate of a transparent conductive film (ITO, indium thin oxide).

<Resin Film>

Another aspect of the present invention provides a polyimide resin film obtained by heating the previously described resin composition. Still another aspect of the present invention provides a method for producing that resin film that includes:

a step for coating the previously described resin composition onto the surface of a support (coating step),

a step for removing the solvent by drying the coated resin composition (drying step),

a step for forming a polyimide resin film by heating the support and the resin composition and imidating the resin precursor contained in the resin composition (heating step), and

a step for separating the polyimide resin film from the support (separation step).

There are no particular limitations on the support in the method for producing a resin film according to the present invention provided it has heat resistance at the drying temperature in a subsequent step and has favorable detachability. Examples thereof include, glass (such as non-alkali glass) substrates; silicon wafers; resin substrates such as those made of polyethylene terephthalate (PET) or oriented polypropylene (OPP); and, substrates composed of stainless steel, alumina, copper, nickel, polyethylene glycol terephthalate, polyethylene glycol naphthalate, polycarbonate, polyimide, polyamide-imide, polyetherimide, polyether ether ketone, polyether sulfone, polyphenylene sulfone or polyphenylene sulfide.

More specifically, a desired polyimide resin film can be formed by coating the resin composition in the present embodiment on an adhesive surface formed on the main surface of the aforementioned substrate and drying, followed by curing by heating at a temperature of 300° C. to 500° C. in an inert atmosphere.

Finally, the resulting polyimide resin film is separated from the support.

A coating method using, for example, a doctor blade coater, air knife coater, roll coater, rotary coater, flow coater, die coater or bar coater; a coating method such as spin coating, spray coating or dip coating; or a printing technology represented by screen printing and gravure printing; can be applied for the coating method.

The coating thickness of the resin composition in the present embodiment is suitably adjusted according to the desired thickness of the polyimide resin film and the solid component concentration in the resin composition. The coating thickness is preferably about 1 μm to 1,000 μm. The coating step may be carried out at room temperature or by heating to a temperature range of 40° C. to 80° C, Use of the latter temperature makes is possible to improve workability of the coating step while lowering viscosity of the res in composition.

The drying step is carried out following the coating step.

The drying step is carried out for the purpose of removing organic solvent. This drying step can be carried out using a suitable device such as a hot plate, compartment dryer or conveyor dryer. The drying temperature is preferably 80° C. to 200° C. and more preferably 100° C. to 150° C.

Continuing, the heating step is carried out. In addition to removing organic solvent remaining in the resin film in the aforementioned drying step, the heating step allows the obtaining of a polyimide resin film, by allowing the polyimide precursor in the coating film to undergo an. imidization reaction.

The heating step can. be carried out using a. device such as an. inert gas oven, hot plate, compartment dryer or conveyor dryer. This step may be carried out simultaneous to the aforementioned drying step or may be carried out in succession following the drying step.

The heating step may be carried out in an air atmosphere or in an inert gas atmosphere. The heating step is preferably carried out in an inert gas atmosphere from the viewpoints of safety as well as the transparency and YI value of the resulting polyimide resin film. Examples of inert gases include nitrogen and argon. Although varying according to the type of the organic solvent (c), the heating temperature in the heating step is preferably 250° C. to 550° C. and more preferably 300° C. to 350° C. If this temperature is 250° C. or higher, imidization proceeds adequately, while if the temperature is 550° C. or lower, a polyimide resin can be obtained that demonstrates a low YI value and high heat resistance. The heating time is preferably about 0.5 hours to 3 hours.

In the case of the present invention, the oxygen concentration in the aforementioned heating step is preferably 2,000 ppm or less, more preferably 100 ppm or less, and even more preferably 10 ppm or less from the viewpoints of transparency and YI value of the resulting polyimide resin film. If the oxygen concentration in the heating step is 2,000 ppm or less, the YI value of the resulting polyimide resin film can be made to be 15 or less by converting based on a film thickness of 10 μm.

A separation step for separating the resulting polyimide resin film from the substrate is necessary following the heating step depending on the application and purpose of use of the polyimide resin film. This separation step is carried out after having cooled the polyimide resin film on the substrate to about room temperature to 50° C.

Examples of this separation step include the methods indicated below.

(1) A method consisting of separating the polyimide resin film by obtaining a laminate consisting of the polyimide resin film and support according to the aforementioned method, followed by irradiating the laminate with a laser from the support side and subjecting the interface between the polyimide resin film and the support to ablation processing. Examples of types of the laser used here include a solid (YAG) laser and a gas (UV excimer) laser. A wavelength of 308 nm, for example, is used for the laser wavelength (see, for example, JP-T 2007-512568 or JP-T 2012-511173).

(2) A method consisting of separating the polyimide resin film after having formed the polyimide resin film on a release layer preliminarily formed on the support to obtain a laminate consisting of the polyimide resin film, release layer, and support. Examples thereof include a method that uses Parylene® (Specialty Coating Systems, Inc.) or tungsten oxide, and a method that uses a vegetable oil-based, silicone-based, fluorine-based or alkyd-based release agent.

(3) A method for obtaining a polyimide resin that uses an etchable metal for the support to obtain a laminate composed of the polyimide resin film and metal support followed by etching the metal substrate with an etchant. Examples of the metal used here include copper (a specific example of which is the electrolytic copper foil “DFF” manufactured by Mitsui Mining & Smelting Co., Ltd.) and aluminum; while examples of the etenant include ferric chloride in the case of copper or dilute hydrochloric acid in the case of aluminum.

(4) A method consisting of obtaining a laminate composed of a polyimide resin film and a support according to the aforementioned method, followed by affixing an adhesive film to the surface of the polyimide resin film, separating the adhesive film/polyimide resin film from the substrate, and then separating the polyimide resin film from the adhesive film.

Among these separation methods, method (1) or (2) is appropriate from the viewpoints of the difference in refractive index between the top and bottom, YI value and elongation of the resulting polyimide resin film, while method (1) is more appropriate from the viewpoint of the difference in refractive index between the top and bottom of the resulting resin film. An aspect in which the aforementioned methods (1) and (2) are used in combination is also preferable (see, for example, JP-A 2010-67957 or JP-A 2013-179306).

In the case of using copper for the support in method (3), the YI value of the resulting polyimide resin film becomes larger and elongation becomes smaller. This is thought to be due to some form, of .involvement, of copper ions.

Although there are no particular limitations thereon, the thickness of the polyimide resin film according to the present embodiment is preferably within the range of 1 μm to 200 μm and more preferably within the range of 5 μm to 100 μm.

The yellowness index of the resin film according to the present embodiment based on a film thickness of 10 μm .is preferably 15 or less. This property is favorably realized by imidating the resin precursor of the present disclosure in a nitrogen atmosphere more preferably at an oxygen concentration of 2,000 ppm or less and temperature of 300° C. to 550°, and particularly preferably 350° C.

<Laminate>

Another aspect of the present invention provides a laminate containing a support and a polyimide resin film formed on the surface of the support that is obtained by heating the previous1y described resin composition.

Still another aspect of the present invention provides a method for producing a laminate that includes: a step for coating the previously described resin composition on the surface of a support (coating step), and

a step for forming a polyimide resin film by heating the support and the resin, composition and imidating the polyimide precursor (a) contained in the resin composition to obtain a laminate containing the support and the polyimide resin film (heating step).

This laminate can be produced by, for example, not separating the polyimide resin film, formed in the same manner as the previously described method for producing a resin film, from the support.

This laminate is used, for example, in the production of a flexible device. More specifically, a flexible device provided with a flexible, transparent substrate composed of a polyimide resin film can be obtained by forming an element or circuit on a polyimide resin film formed on a support followed by separating the support.

Thus, another aspect of the present invention provides a flexible device material containing a polyimide resin film obtained by heating the previously described resin composition.

As has been previously explained, a resin composition having superior storage stability and superior coatability can be produced using the polyimide precursor (a) according to the present embodiment. There is little dependence of the yellowness index (YI value) of a polyimide resin film obtained from this resin composition on oxygen concentration during curing. Thus, the resin composition is suitable for use in a transparent substrate of a flexible display.

The polyimide resin film according to the present embodiment preferably has a yellowness index of 15 or less based on a film thickness of 10 μm.

In general, the low level of dependence on oxygen concentration in the oven used when preparing the polyimide resin film is advantageous for stably obtaining a resin film having a low YI value. However, the resin composition according to the present embodiment enables the stable production of a polyimide resin film having a low YI value at an oxygen concentration of 2,000 ppm or less.

The polyimide resin film according to the present embodiment preferably has superior breaking strength from the viewpoint of improving yield when handling a flexible substrate. In quantitative terms, the tensile elongation of the polyimide resin film is preferably 30% or more.

Another aspect of the present .invention provides a polyimide resin film that is used to produce a display substrate. Still another aspect of the present invention provides a method for producing a display substrate that includes:

a step for coating the resin composition according to the present embodiment onto the surface of a support (coating step),

a step for forming the previously described polyimide resin film by heating the support and the resin composition and imidating the polyimide precursor (a) (heating step),

a step for forming an element or circuit on the polyimide resin film (mounting step), and

a step for separating the polyimide resin film having the element or circuit formed thereon (separation step).

In the aforementioned method, the coating step, heating step and separation step can each be carried out in the same manner as in the previously described methods for producing the polyimide resin film and laminate.

The resin film according to the present embodiment that satisfies the aforementioned properties is preferably used in applications in which the use of existing polyimide films is limited due to yellowing thereof, and particularly in applications such as colorless, transparent substrates for flexible displays or protective films for color filters. The resin film according to the present embodiment can also be used in diffuser sheet and coating film applications in protective films and TFT-LCD (such as the inter-layers, gate insulating films or liquid crystal alignment films of TFT-LCD); and in fields requiring absence of color, transparency and low birefringence such as ITO substrates for touch panels or alternative cover glass resin substrates for cellular telephones. Application of the polyimide according to the present embodiment as a liquid crystal alignment film contributes to an increase in aperture ratio and enables the production of TFT-LCD having a high contrast ratio.

A resin film and laminate produced using the resin precursor according to the present embodiment can be used particularly preferably as a substrate in the production of, for example, a semiconductor insulating film, TFT-LCD insulating film, electrode protective film or flexible device. Examples of flexible devices include flexible displays, flexible solar cells, flexible touch panel electrode substrates, flexible illumination and flexible batteries.

### EXAMPLES

The following provides a more detailed description of the present invention based on examples thereof. These examples are described for the purpose of explanation, and the scope of the present invention is not limited by the following examples.

Various evaluations in the examples and comparative examples were carried out in the manner described below.

(Preparation of Polyimide Resin Film and Laminate)

Polyamic acid was coated onto non-alkali glass (Corning Inc., 10 cm×10 cm×0.7 mm) using a spin coater (Mikasa Corp.) so that the film thickness after curing was 10 μm, followed by pre-baking for 30 minutes at 100° C. on a not plate. Subsequently, a laminate was obtained having the aforementioned polyimide film formed on the aforementioned glass substrate by curing by heating for 1 hour at 350° C. in a curing oven (Koyo Lindbergh Co.) under a nitrogen atmosphere.

(Evaluation of Adhesiveness)

The laminate having a polyimide film (film thickness: 10 μm) formed on a glass substrate obtained as previously described was cut out to a width of 2.5 cm, and after having slightly separated the polyimide film from the glass substrate, peel strength was measured at a peel angle of 180° and peel rate of 50 mm/min in an atmosphere at 23° C. and 50% RH using an autograph,

(Measurement of Laser Peel Strength)

A laminate, obtained according to the previously described coating method and curing method and having a polyimide film having a film thickness of 10 μm on non-alkali glass, was irradiated with an excimer laser (wavelength: 308 nm, pulse rate: 300 Hz) followed by determination of the minimum energy required to lift off the entire polyimide film measuring 10 cm×10 cm,

<Measurement of Weight Average Molecular Weight and Number Average Molecular Weight>

Weight average molecular weight (Mw) and number average molecular weight (Mn) were respectively measured under the following conditions by gel permeation chromatography (GPC).

Solvent: Solution obtained by adding lithium bromide monohydrate (Wako Pure Chemical Industries, Ltd., purity: 99.5%) having a concentration of 24.8 mmol/L prior to measurement and phosphoric acid (Wako Pure Chemical Industries, Ltd., for high-performance liquid chromatography) having a concentration of 63.2 mmol/L prior to measurement to N,N-dimethylformamide (Wako Pure Chemical Industries, Ltd., for high-performance liquid chromatography)

Calibration curve for calculating weight average molecular weight: Prepared using standard polystyrene (Toson Corp.)

Column: Shodex KD-806M (Showa Denko K.K.)

Flow rate: 1.0 mL/min

Column temperature: 40° C.

Pump: PU-2080 Plus (Jasco Corp.)

Detector: RI-2031 Plus (RI: differential refractometer, Jasco Corp.) and UV-2075

Plus (UV-VTS: UV-visible spectrometer (Jasco Corp.)

(Evaluation of Yellowness Index (YI Value))

Each resin composition prepared in the examples and comparative examples was coated onto a 6-inch silicon wafer substrate provided with an aluminum deposition layer on the surface thereof so that the film thickness after curing was 10 μm to form a coating film on the aforementioned substrate. After prebaking the substrate having a coating film thereon for 60 minutes at 80° C., a wafer having a polyimide resin film formed thereon was fabricated by carrying out heat-curing treatment for 1 hour at 350° C. using a vertical curing oven (Model VF-2000B, Koyo Lindbergh Co.) . This wafer was then immersed in dilute aqueous hydrochloric acid solution to separate the polyimide resin.

The YI value (based on a film thickness of 10 μm) of the resulting polyimide film was measured with the SE600 Spectrophotometer manufactured by Nippon Denshoku Industries Co., Ltd. using a D65 illuminant.

<Synthesis of Alkoxysilane Compound>

### Synthesis Example 1

19.5 g of N-methyl-2-pyrrolidone (NMP) were placed in a separable flask having a volume of 50 mL for which the inside thereof had been replaced with nitrogen followed by the further addition of 2.42 g (7.5 mmol) of benzophenonetetracarboxylic dianhydride (BTDA) as a Raw Material Compound 1 and 3.321 g (15 mmol) of 3-aminopropyltriethoxysilane (trade name: LS-3150, Shin-Etsu Chemical Co., Ltd.) as a Raw Material Compound 2, and reacting for 5 hours at room temperature to obtain an NMP solution of Alkoxysilane Compound 1.

### Synthesis Examples 2 to 4

NMP solutions of Alkoxysilane Compounds 2 to 4 were obtained in the same manner as Synthesis Example 1 with the exception of changing the amount of N-methy-2-pyrrolidone (NMP) used and the types and amounts of Raw Material Compounds 1 and 2 used to those respectively described in Table 1.

TABLE 1

| | | | Raw Material | | | | | |
|---|---|---|---|---|---|---|---|---|
| | | | Compound 1 | | | Raw Material Compound 2 | | |
| | | Amount of | | Amount Used | | | Amount Used | |
| | Name | NMP Used | Type | (g) | (mmol) | Type | (g) | (mmol) |
| Synthesis | Alkoxysilane | 19.5 | BTDA | 2.42 | 7.5 | LS-3150 | 3.32 | 15 |
| Example 1 | Compound 1 | | | | | | | |
| Synthesis | Alkoxysilane | 19.5 | BPDA | 2.21 | 7.5 | LS-3150 | 3.32 | 15 |
| Example 2 | Compound 2 | | | | | | | |
| Synthesis | Alkoxysilane | 13.2 | ANPH | 1.23 | 8.0 | LS-3415 | 2.08 | 8.0 |
| Example 3 | Compound 3 | | | | | | | |
| Synthesis | Alkoxysilane | 9.8 | DACA | 0.78 | 4.0 | LS-3415 | 1.97 | 8.0 |
| Example 4 | Compound 4 | | | | | | | |

The abbreviations of the names of compounds shown in Table 1 respectively have the meanings indicated below.

[Raw Material Compound 1]

BTDA: Benzophenonetetracarboxylic dianhydride

BPDA: Bipheny1tetracarboxylic dianhydride

ANPH: 2-amino-4-nitrophenol

DACA: 3,6-diaminocarbazole

[Raw Material Compound 2]

LS-3150: trade name, Shin-Etsu Chemical Co., Ltd., 3-aminopropyltriethoxysilane

LS-3415: trade name, Shin-Etsu Chemical Co., Ltd., 3-isocyanatopropyltriethoxy silane

[Measurement of Absorbance of Alkoxysilane Compound at 308 nm]

NMP solutions having a concentration of 0.001% by weight were respectively prepared from the aforementioned Alkoxysilane Compounds 1 to 4 followed by filling into a quartz cell having a measuring thickness of 1 cm and measuring absorbance at a wavelength of 308 nm using the UV-1600 (Shimadzu Corp.). The results are shown in Table 2.

Table 2 also indicates the absorbance of (3-triethoxysilylpropyl)-t-butylcarbamate (Gelest Inc.) (Alkoxysilane Compound 5) using the same procedure.

TABLE 2

| | Absorbance |
|---|---|
| Alkoxysilane Compound 1 | 0.130 |
| Alkoxysilane Compound 2 | 0.177 |
| Alkoxysilane Compound 3 | 0.229 |
| Alkoxysilane Compound 4 | 0.208 |
| Alkoxysilane Compound 5 | 0.003 |

<Synthesis of Polyimide Precursor>

### Synthesis Example 5

The inside of a 500 ml separable flask was replaced with nitrogen, N-methyl-2-pyrrolidone (NMP) as a solvent was placed in the separable flask so that the solid component concentration was 15% by weight after polymerization, and 15.69 g (49.0 mmol) of 2,2′-bis(trifluoromethyl)benzidine (TFMB) as a diamine is added followed by stirring to dissolve the TFMB. Subsequently, 9.82 g (45.0 mmol) of pyromellit.ic dianhydride (PMDA) and 2.22 g (5.0 mmol) of 4,4′-(hexafluoroisopropylidene)diphthalic anhydride (6FDA) as tetracarboxylic dianhydrides were added. Next, synthesis was carried out for 4 hours at 80° C. under flowing nitrogen.

After cooling to room temperature, NMP was added to adjust the solution viscosity to 51,000 mPa·s and obtain Polyamic Acid NMP Solution P-1. The weight average molecular weight (Mw) of the resulting polyamic acid was 180,000.

### Synthesis Examples 6 to 11

Polyamic Acid NMP Solutions P-2 to P-7 were obtained in the same manner as Synthesis Example 5 with the exception of respectively using the types and amounts of diamine and tetracarboxylic dianhydride shown in Table 3, The weight average molecular weights (Mw) of the resulting polyamic acids are also shown in Table 3.

[Measurement of Absorbance of Polyimide Resin Films at 308 nm]

Each of the aforementioned Solutions P-1 to P-7 was spin-coated onto a quartz glass substrate followed by heating for 1 hour at 350° C. in a nitrogen atmosphere to respectively obtain polyimide resin films having a film thickness of 0.1 μm. The absorbances of these polyimide resin films at 308 nm were measured using the UV-1600 (Shimadzu Corp.). The results are shown in Table 3.

TABLE 3

| | | Tetracarboxylic | | | | | | | |
|---|---|---|---|---|---|---|---|---|---|
| | | Dianhydride | | | Diamine | | | Weight | |
| | | | Amount | | | Amount | | Average Molecular | Absorbance |
| | Polymer | Type | (g) | (mmol) | Type | (g) | (mmol) | Weight (Mw) | @0.1 μm |
| Synthesis | P-1 | PMDA | 9.82 | 45.0 | TFMB | 15.69 | 49.0 | 180,000 | 0.17 |
| Example 5 | | 6FDA | 2.22 | 5.0 | | | | | |
| Synthesis | P-2 | PMDA | 2.18 | 10.0 | TFMB | 15.69 | 49.0 | 201,000 | 0.11 |
| Example 6 | | 6FDA | 17.77 | 40.0 | | | | | |
| Synthesis | P-3 | PMDA | 8.72 | 40.0 | TFMB | 15.69 | 49.0 | 208,000 | 0.23 |
| Example 7 | | ODPA | 3.10 | 10.0 | | | | | |
| Synthesis | P-4 | BPDA | 14.71 | 50.0 | 4,4′-DAS | 12.17 | 49.0 | 56,000 | 0.36 |
| Example 8 | | | | | | | | | |
| Synthesis | P-5 | BPDA | 14.71 | 50.0 | TFMB | 10.98 | 34.3 | 103,000 | 0.58 |
| Example 9 | | | | | 4,4′-DAS | 3.65 | 14.7 | | |
| Synthesis | P-6 | CHDA | 11.21 | 50.0 | TFMB | 15.69 | 49.0 | 38,000 | 0.07 |
| Example 10 | | | | | | | | | |
| Synthesis | P-7 | BPDA | 14.71 | 50.0 | p-PD | 5.30 | 49.0 | 294,000 | 1.07 |
| Example 11 | | | | | | | | | |

The abbreviations of the names of compounds shown in Table 3 respectively have the meanings indicated below.

(Diamines)

TFMB: 2,2′-bis(trifluoromethyl)benzidine 4,4′-DAS: 4,4′-(diaminodiphenyl)sulfone

p-PD: 1,4-diaminobenzene

(Tetracarboxylic dianhydrides)

PMDA: Pyromellitic dianhydride

6FDA: 4,4′-(hexafluoroisopropylidene)diphthalic anhydride

ODPA.: 4,4′-oxydiphthalic dianhydride

BPDA.: 3,3′,4,4′-biphenyItetracarboxylie dianhydride

CHDA: Cyclohexane-1,2,4,5-tetracarboxylie dianhydride

### Examples 1 to 8 and Comparative Examples 1-4

Resin compositions containing polyamic acid as a polyimide precursor were respectively prepared by charging the types of polyamic acid solutions and alkoxysilane compounds shown in Table 4 in the amounts shown therein into a container and stirring well.

The adhesiveness, laser detachability and YI values measured for each of the aforementioned resin compositions according to the methods previously described are respectively shown in Table 4. The polyimide resin films were unable to be separated in “measurement of laser peel strength” even if laser intensity was increased up to 300 mJ/cnf in Comparative Examples 2 and 3. The YI value exceeded 30 in Comparative Example 4.

TABLE 4

| | Polyamic Acid Solution | | Alkoxysilane Compound | | Adhesiveness | Laser Peel Strength | |
|---|---|---|---|---|---|---|---|
| | Solution Type | Amount (g) | Type | Amount (mg) | (gf/inch) | (mJ/cm²) | YI |
| Example 1 | P-1 | 10 | Alkoxysilane Compound 1 | 10.5 | 877 | 220 | 6.5 |
| Example 2 | P-1 | 10 | Alkoxysilane Compound 2 | 10.5 | 937 | 210 | 6.7 |
| Example 3 | P-1 | 10 | Alkoxysilane Compound 3 | 10.5 | 690 | 220 | 8.4 |
| Example 4 | P-1 | 10 | Alkoxysilane Compound 4 | 10.5 | 750 | 220 | 9.9 |
| Example 5 | P-2 | 10 | Alkoxysilane Compound 1 | 10.5 | 876 | 220 | 4.8 |
| Example 6 | P-3 | 10 | Alkoxysilane Compound 1 | 10.5 | 890 | 210 | 7.5 |
| Example 7 | P-4 | 10 | Alkoxysilane Compound 1 | 10.5 | 882 | 200 | 2.7 |
| Example 8 | P-5 | 10 | Alkoxysilane Compound 1 | 10.5 | 883 | 190 | 2.5 |
| Comp. Ex. 1 | P-1 | 10 | — | — | 100 | 240 | 6.6 |
| Comp. Ex. 2 | P-1 | 10 | Alkoxysilane Compound 5 | 10.5 | 423 | Unpeelable*⁾ | 6.6 |
| Comp. Ex. 3 | P-6 | 10 | Alkoxysilane Compound 1 | 10.5 | 872 | Unpeelable*⁾ | 2.1 |
| Comp. Ex. 4 | P-7 | 10 | Alkoxysilane Compound 1 | 10.5 | 889 | 180 | >30 |

*⁾Unable to be separated even at 300 mJ/cm²

Based on the above results, the polyimide film obtained from the resin composition according to the present invention was confirmed to be a resin film that has a low yellowness index, demonstrates high adhesive strength with a glass substrate, and requires little energy for laser lift off.

The present invention is not limited to the aforementioned embodiment., but rather can be carried out by modifying in various ways.

### INDUSTRIAL APPLICABILITY

The present invention can be preferably applied as, for example, a semiconductor insulating film, TFT-LCD insulating film, electrode protective film, flexible display electrode or a substrate for a touch panel ITO electrode. The present invention is particularly preferably used as a substrate.

1. A resin composition, comprising
(a) a polyimide precursor having absorbance at 308 nm of 0.1 to 0.8 when heated for 1 hour at 350° C. to form a polyimide resin film having a film thickness of 0.1 μm, and
(b) an alkoxysilane compound having absorbance at 308 nm of 0.1 to 1.0 when in the form of a 0.001% by weight NMP solution at a solution thickness of 1 cm.

2. The resin composition according to claim 1, wherein the alkoxysilane compound of (b) is the reaction product of a tetracarboxylic dianhydride represented by the following general formula (1): 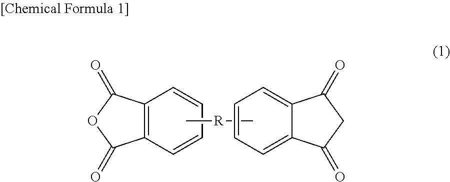
(wherein, R represents a single bond, oxygen atom, sulfur atom, carbonyl group or alkylene group having 1 to 5 carbon atoms), and
an aminotrialkoxysilane compound.

3. The resin composition according to claim 1, wherein the alkoxysiiane compound of (b) is at least one type of compound selected from the group of consisting of compounds respectively represented by the following general formulas (2) to (4), (9) and (10).

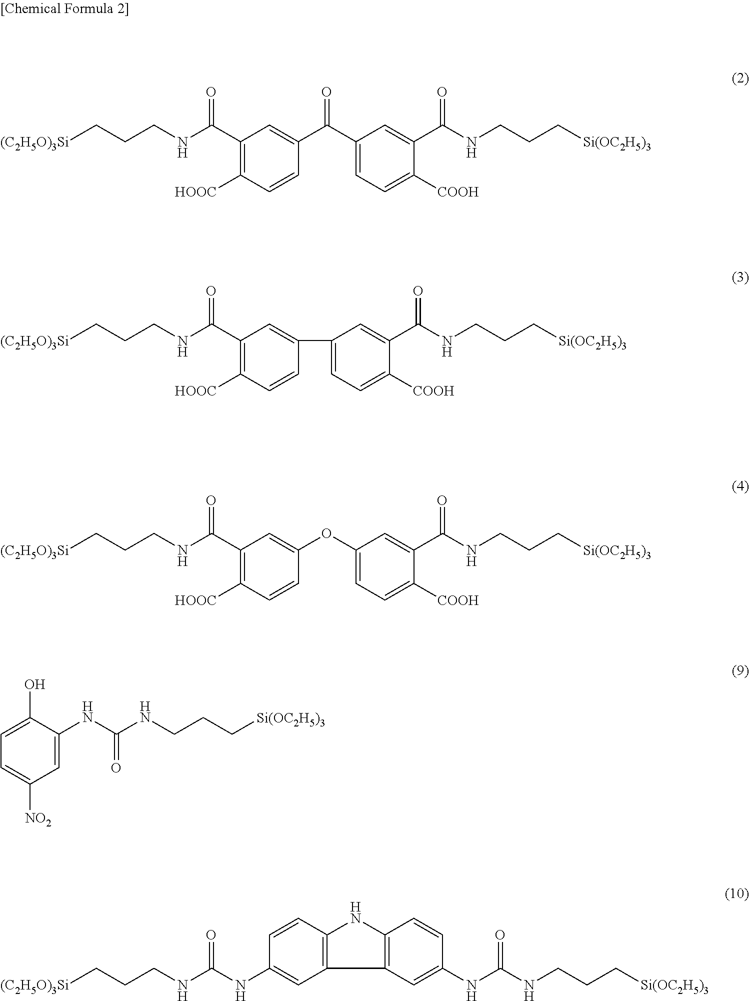

4. The resin composition according to claim 1, wherein the polyimide precursor of (a) has one or more structural units selected from the structural units respectively represented by the following formulas (5) and (6): 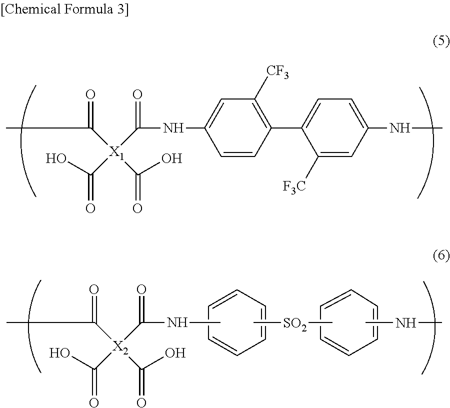
(wherein, X₁ and X₂ respectively and independently represent a tetravalent organic group having 4 to 32 carbon atoms).

5. The resin composition according to claim 4, wherein the polyimide precursor of (a) has a structural unit represented by the following formula (5-1): 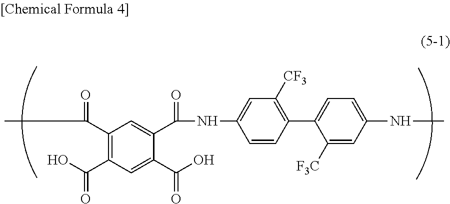
and a structural unit represented by the following formula (5-2).

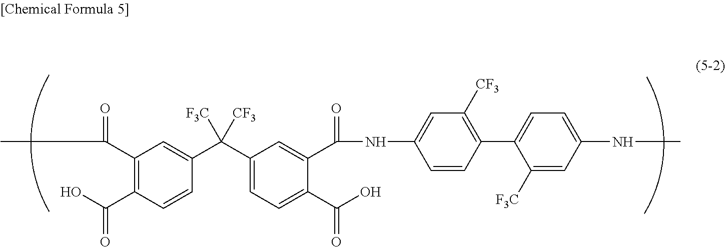

6. The resin composition according to claim 5, wherein the molar ratio of the structural unit represented by the formula (5-1) to the structural unit represented by the formula (5-2) is 90/10 to 50/50.

7. The resin composition according to claim 4, wherein the polyimide precursor of (a) has a structural unit represented by the following formula (6-1).

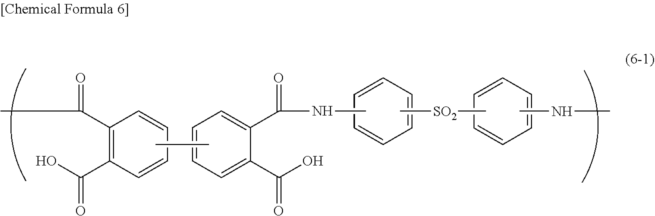

8. A polyimide resin film, which is a cured product of the resin composition according to claim 1.

9 A resin film, comprising the polyimide resin film according to claim 8.

10. A method for producing a polyimide resin film, comprising:
a step for coating the resin composition according to claim 1 on the surface of a support,
a step for drying the coated resin composition and removing the solvent,
a step for heating the support and the resin composition to form a polyimide resin film, and
a step for separating the polyimide resin film from the support.

11. The method for producing a polyimide resin film according to claim 10, wherein the step for separating the polyimide resin film from the support comprises a step for separating the polyimide resin film after irradiating with laser light from the support side.

12. A laminate comprising a support and a polyimide resin film which is a cured product of the resin composition according to claim 1 on the surface of the support.

13. A method for producing a laminate, comprising:
a step for coating the resin composition according to claim 1 on the surface of a support,
a step for drying the coated resin composition and removing the solvent, and
a step for heating the support and the resin composition to form a polyimide resin film.

14. A method for producing a display substrate, comprising:
a step for coating the resin composition according to claim 1 on a support,
a step for drying the coated resin composition and removing the solvent,
a step for heating the support and the resin composition to form a polyimide resin film,
a step for forming an element or circuit on the polyimide resin film, and
a step for separating the polyimide resin film having an element or circuit formed thereon from the support.
